(19) United States
(12) Patent Application Publication
(10) Pub. No.: US 2025/0253274 A1
(43) Pub. Date: Aug. 7, 2025

(54) ELECTRONIC DEVICE AND MANUFACTURING METHOD THEREOF

(71) Applicant: InnoLux Corporation, Miao-Li County (TW)

(72) Inventors: Yen-Fu LIU, Miao-Li County (TW); Der-Yi HSU, Miao-Li County (TW)

(73) Assignee: InnoLux Corporation, Miao-Li County (TW)

(21) Appl. No.: 19/023,408

(22) Filed: Jan. 16, 2025

Related U.S. Application Data
(60) Provisional application No. 63/549,581, filed on Feb. 5, 2024.

(30) Foreign Application Priority Data
Sep. 23, 2024 (CN) 202411319755.8

(51) Int. Cl. H01L 23/00; H01L 23/498

(52) U.S. Cl. CPC H01L 24/05; H01L 23/49816; H01L 24/03; H01L 24/19; H01L 24/20; H01L 2224/0363; H01L 2224/05541; H01L 2224/05578; H01L 2224/19; H01L 2224/211; H01L 2224/214; H01L 2924/37001

(57) ABSTRACT

An electronic device is disclosed. The electronic device includes a semiconductor structure, an insulation layer and a circuit structure. The semiconductor structure includes a connection pad including a first portion and a second portion, and the first portion is connected to the second portion. The insulation layer is disposed on the semiconductor structure and includes an opening, and the opening exposes the first portion of the connection pad. The circuit structure is disposed on the insulation layer and includes a conductive layer, and the conductive layer is disposed in the opening and overlapped with the first portion of the connection pad. The first portion of the connection pad has a first thickness, the second portion of the connection pad has a second thickness, and a ratio of the second thickness to the first thickness is greater than or equal to 1 and less than or equal to 1.3.

### CROSS REFERENCE TO RELATED APPLICATION

This application claims the benefit of U.S. Provisional Application No. 63/549, 581, filed on Feb. 5, 2024. The content of the application is incorporated herein by reference.

### BACKGROUND OF THE DISCLOSURE

### 1. Field of the Disclosure

The present disclosure relates to an electronic device and a manufacturing method thereof, and particularly to an electronic device including a semiconductor structure with a connection pad and a manufacturing method thereof.

### 2. Description of the Prior Art

In recent years, electronic components in standard electronic devices have become smaller and denser. This has led to the development of diversified package technologies, wherein wirings of the electronic components may be redistributed through a circuit structure. As contact resistance between the circuit structure and the electronic component is large, however, the conductivity quality is affected. This is an issue in the field that needs to be improved.

### SUMMARY OF THE DISCLOSURE

It is an objective of the present disclosure to provide an electronic device and a manufacturing method thereof, wherein via a structural design of a connection pad of a semiconductor structure and an opening overlapped with the connection pad, the contact resistance between the conductive layer disposed in the opening and the connection pad may be reduced, such that the conductivity quality is enhanced.

An embodiment of the present disclosure provides an electronic device including a semiconductor structure, an insulation layer, and a circuit structure. The semiconductor structure includes a connection pad, wherein the connection pad includes a first portion and a second portion, and the first portion is connected to the second portion. The insulation layer is disposed on the semiconductor structure, wherein the insulation layer includes an opening, and the opening exposes the first portion of the connection pad. The circuit structure is disposed on the insulation layer, wherein the circuit structure includes a conductive layer, and the conductive layer is disposed in the opening and overlapped with the first portion of the connection pad. The first portion of the connection pad has a first thickness, the second portion of the connection pad has a second thickness, and a ratio of the second thickness to the first thickness is greater than or equal to 1 and less than or equal to 1.3.

An embodiment of the present disclosure provides a manufacturing method of an electronic device, which includes: providing a semiconductor structure, wherein the semiconductor structure includes a connection pad; forming an insulation layer on the semiconductor structure; patterning the insulation layer to form a first hole, wherein the first hole exposes a portion of the connection pad; patterning the insulation layer to form a second hole, wherein the second hole exposes another portion of the connection pad, the second hole partially overlaps the first hole, and the first hole and the second hole constitute the opening; and forming a conductive layer in the opening such that the conductive layer is connected to the connection pad.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to an embodiment of the present disclosure.

FIG. 2 schematically illustrates a partial enlarged view of the electronic device shown in FIG. 1.

FIG. 3A schematically illustrates a partial top view of a connection pad and an opening according to some embodiments of the present disclosure.

FIG. 3B schematically illustrates a partial top view of a connection pad and an opening according to some other embodiments of the present disclosure.

FIG. 4 schematically illustrates a partial enlarged view of an electronic device according to some embodiments of the present disclosure.

FIG. 5 schematically illustrates a cross-sectional view of an electronic device according to another embodiment of the present disclosure.

FIG. 6 schematically illustrates a flow chart of a manufacturing method of an electronic device according to an embodiment of the present disclosure.

FIG. 7, FIG. 8A, FIG. 8B, FIG. 9A, FIG. 9B, and FIG. 10 schematically illustrate a partial process of a manufacturing method of an electronic device according to an embodiment of the present disclosure.

FIG. 11 schematically illustrates a partial process of a manufacturing method of an electronic device according to an embodiment of the present disclosure.

FIG. 12 schematically illustrates a moving path of a laser module according to some embodiments of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure only illustrate a portion of the device or the structure, and elements therein may not be drawn to scale. The numbers and sizes of the components in the drawings are merely illustrative and are not intended to limit the scope of the present disclosure.

Certain terms are used throughout the specification and the appended claims of the present disclosure to refer to specific components. Those skilled in the art should understand that electronic equipment manufacturers may refer to a component by different names, and this document does not intend to distinguish between components that differ in name but not in function. In the following specification and claims, the terms “comprise”, “include” and “have” are open-ended fashion, so they should be interpreted as “including but not limited to . . . ”. The terms “comprise”, “include” and “have” are used in the specification to indicate the existence of the character, region, step, operation, and/or component but do not rule out the existence or the addition of one or more other characters, regions, steps, operations, components, and/or a combination thereof.

When one component or layer is “on” or “above” another component or layer or is “connected to” the other component or layer, it may be understood that the component or layer is directly on the other component or layer or directly connected to the other component or layer, and alternatively, another component or layer may be between the component or layer and the other component or layer (indirectly). When the component or layer is “directly on” the other component or layer or is “directly connected to” the other component or layer, it may be understood that there is no intervening component or layer between the component or layer and the other component or layer.

The term “connected to” in the present disclosure may represent a physical connection or an electrical connection and may include any direct or indirect means of connection. The term “disposed on” in the present disclosure is used for describing a relative position between the components and does not limit the manufacturing procedure or sequence thereof. The term “surround” in the present disclosure may represent that, in a cross-sectional view, at least a portion of a surrounded component or layer is disposed in another component or layer. In some embodiments, the other component or layer may further contact a side surface of the corresponding surrounded component or layer.

Spatially relative terms, such as “above”, “on”, “beneath”, “below”, “under”, “left”, “right”, “before”, “front”, “after”, “behind” and the like, used in the following embodiments merely refer to the directions in the drawings and are not intended to limit the present disclosure.

As disclosed herein, the terms “approximately”, “essentially”, “about”, or “substantially” generally mean within 20% or generally mean within 10%, 5%, 3%, 2%, 1%, or 0.5% of the reported numerical value or range.

The ordinal numbers used in the specification and the appended claims, such as “first”, “second”, etc., are used to describe the components of the claims. This does not mean that the component has any previous ordinal numbers, nor does this represent the order of a certain component and another component, or the sequence in a manufacturing method. These ordinal numbers are merely used to make a claimed component with a certain name be clearly distinguishable from another claimed component with the same name. The same term may not be used in both the appended claims and the specification; hence, a first component in the specification may be a second component in the appended claims.

In the present disclosure, the thickness, length, width of each component, and/or the distance between the components may be measured by using an optical microscope (OM), a scanning electron microscope (SEM) or other approaches. For example, the thickness, length, width of each component, and/or the distance between the components may be measured from an image obtained from the SEM, but not limited thereto.

An electronic device of the present disclosure may, for example, be applied to a power module, a semiconductor package device, a display device, a light emitting device, a backlight device, an antenna device, a sensing device, or a tiled device, but not limited thereto. The electronic device may be a bendable or flexible electronic device. The display device may be a non-self-emitting display device or a self-emitting display device. The antenna device may include liquid crystal antenna or antennas of other types, and the sensing device may be a sensing device used for detecting variation in capacitances, light, heat, or ultrasound, but not limited thereto. The electronic device may include a passive element, an active element, or other electrical elements, such as a capacitor, a resistor, an inductor, a diode, a transistor, etc. The diode may include a light emitting diode or a photodiode. The light emitting diode may, for example, include an organic light emitting diode (OLED), a mini light emitting diode (mini LED), a micro light emitting diode (micro LED), a quantum dot light emitting diode (e.g., QLED or QDLED), but not limited thereto. The tiled device may, for example, include a tiled display device or a tiled antenna device, but not limited thereto. It is noted that the electronic device may be any combination of the aforementioned devices, but not limited thereto.

The manufacturing method of the electronic device of the present disclosure may, for example, be applied to a wafer-level package (WLP) process or a panel-level package (PLP) process and may be a chip-first process or a chip-last process (or may be referred to as a redistribution layer first, RDL-first, process), but not limited thereto.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

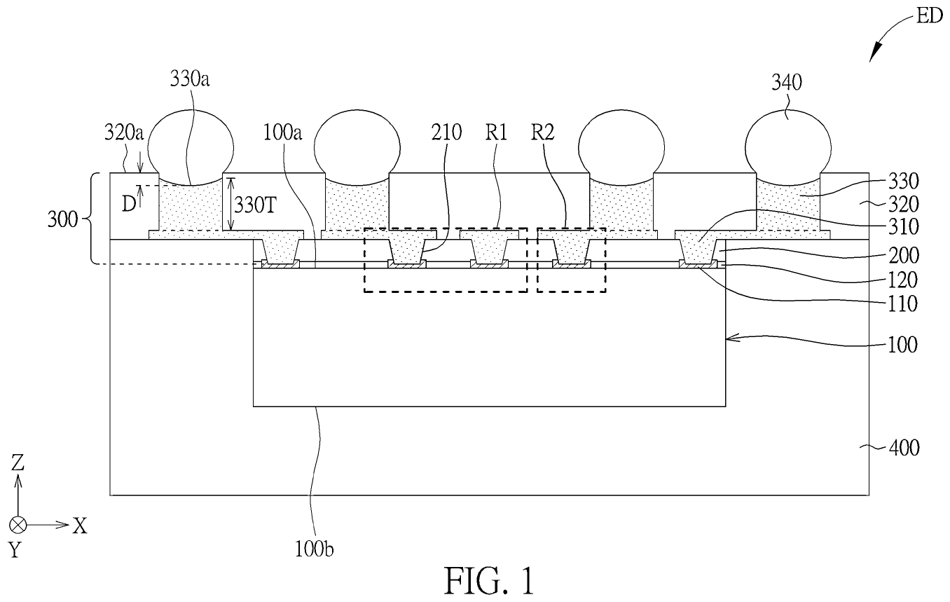

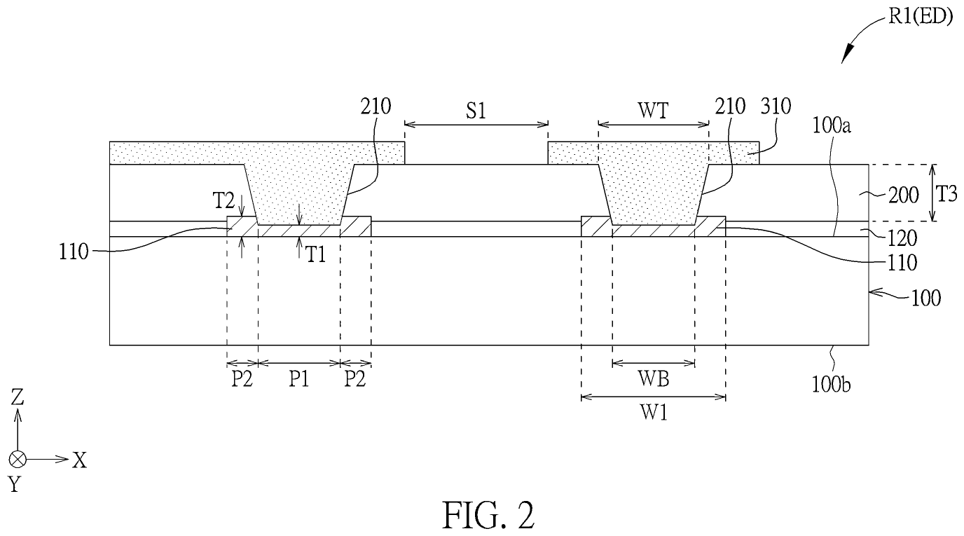

Refer to FIG. 1 and FIG. 2. FIG. 1 schematically illustrates a cross-sectional view of an electronic device according to an embodiment of the present disclosure. FIG. 2 schematically illustrates a partial enlarged view of the electronic device shown in FIG. 1, wherein FIG. 2 may be an enlarged view of a region R1 in FIG. 1. As shown in FIG. 1 and FIG. 2, an electronic device ED of an embodiment of the present disclosure includes a semiconductor structure 100, an insulation layer 200, and a circuit structure 300. The semiconductor structure 100 includes a connection pad 110, wherein the connection pad 110 includes a first portion P1 and a second portion P2, and the first portion P1 is connected to the second portion P2. The semiconductor structure 100 may, for example, include one or a plurality of the connection pads 110, and the quantity may be adjusted according to requirements in practice. A surface of the semiconductor structure 100, on which the connection pads 110 are disposed, may be referred as an active surface 100a, and the semiconductor structure 100 may further include a rear surface 100b opposite to the active surface 100a, i.e. the active surface 100a and the rear surface 100b are disposed on two opposite sides of the semiconductor structure 100, and the plurality of connection pads 110 are disposed on the active surface 100a. The semiconductor structure 100 may, for example, be a chip, a die, an integrated circuit (IC), or other suitable semiconductor elements, but is not limited thereto.

The insulation layer 200 is disposed on the semiconductor structure 100, wherein the insulation layer 200 includes openings 210, and the openings 210 expose the first portions P1 of the connection pads 110. The insulation layer 200 may include organic materials, such as polyimide (PI), photosensitive polyimide (PSPI), epoxy, polymer, or other suitable materials. The insulation layer 200 may further include fillers, wherein a diameter (i.e., particle size) of the filler may be 0.05 micrometers (μm) to 20 micrometers. A coefficient of thermal expansion (CTE) of the insulation layer 200 is 10 millionths per Celsius (ppm/° C.) to 50 ppm/° C. A Young's modulus of the insulation layer 200 is 3 trillion pascals (GPa) to 30 GPa. A tensile strength of the insulation layer 200 is 50 million pascals (MPa) to 110 MPa. The insulation layer 200 may be used to buffer the acting forces during a cutting process. In some embodiments, the semiconductor structure 100 may further include a passivation layer 120 partially covering the connection pads 110: for example, the passivation layer 120 may cover side surfaces of the connection pads 110 to protect the connection pads 110, and the insulation layer 200 may be disposed on the second portions P2 of the connection pads 110 and the passivation layer 120, but not limited thereto.

The circuit structure 300 is disposed on the insulation layer 200, wherein the circuit structure 300 includes a conductive layer 310, and the conductive layer 310 is disposed in the openings 210 and overlapped with the first portions P1 of the connection pads 110. The first portions P1 of the connection pad 110 have a first thickness T1, the second portions P2 of the connection pads 110 have a second thickness T2, and a ratio of the second thickness T2 to the first thickness T1 is greater than or equal to 1 and less than or equal to 1.3 (1≤T2/T1≤1.3). In another embodiment, the ratio of the second thickness T2 to the first thickness T1 is greater than or equal to 1 and less than or equal to 1.2 (1<T2/T1≤1.2). Specifically, a portion of the conductive layer 130 disposed in one opening 210 may be overlapped with the first portion P1 of one connection pad 110 in a direction Z, and the conductive layer 310 may be electrically connected to and in contact with the connection pad 110 of the semiconductor structure 100 through the opening 210 of the insulation layer 200. In the present disclosure, the direction Z may be a normal direction of the electronic device ED and may be parallel to a top view direction of the electronic device ED. For example, the direction Z may be parallel to a normal direction of the active surface 100a or the rear surface 110b of the semiconductor structure 100. In addition, the direction Z may be perpendicular to a direction X and a direction Y, and the direction X may be perpendicular to the direction Y, wherein the direction X may be parallel to a horizontal direction in the cross-sectional view, but not limited thereto.

In some embodiments, as shown in FIG. 2, a surface of the first portion P1 of the connection pad 110 may have a recess, wherein the ratio of the second thickness T2 to the first thickness T1 is greater than 1 and less than or equal to 1.3, such that there is a gap between an upper surface of the second portion P2 of the connection pad 110 and an upper surface of the first portion P1 of the connection pad 110, and a portion of the conductive layer 310 may be disposed in the recess, but not limited thereto. For example, in the manufacturing process of the electronic device ED, a plurality of holes partially overlapped with each other may be formed by a laser module to constitute the opening 210, and the overlapping holes may result in the surface recess of the first portion P1, wherein detailed steps of the aforementioned process will be further elaborated in the following contents.

According to the embodiment shown in FIG. 1, the circuit structure 300 may further include at least one insulation layer 320 and at least one conductive layer 330 stacked on the conductive layer 310 in the direction Z to constitute a redistribution structure, such that the wirings may be redistributed, and/or the fan-out area of the wirings may be further enhanced. In some embodiments, the electronic device ED may further include a plurality of bonding elements 340 respectively electrically connected to the circuit structure 300. Specifically, the insulation layer 320 of the circuit structure 300 may expose an upper surface 330a of the conductive layer 330 disposed on the top layer, and the plurality of bonding elements 340 may be disposed on the exposed upper surface 330a of the conductive layer 330, such that the plurality of bonding elements 340 may respectively be electrically connected to one of the connection pads 110 of the semiconductor structure 100 through the conductive layer 330 and the conductive layer 310. The bonding element 340 may be a bump, a pad, a solder ball, or other suitable bonding elements, and the bonding element 340 may, for example, include copper, tin, nickel, gold, lead, silver, gallium, other suitable conductive materials, or a combination of the aforementioned materials, but not limited thereto. The manufacturing method of forming the redistribution structure may, for example, include a lithography process, an etching process, a surface treatment process, a laser process, an electroplating process, an electroless plating process, a deposition process, etc. In some embodiments, as shown in FIG. 1, the recesses may be formed on the upper surface 330a of the conductive layer 330 through the etching process, and the bonding elements 340 may be filled in the recesses and electrically connected to the conductive layer 330, wherein a maximum distance Dis between the upper surface 330a of the conductive layer 330 and an upper surface 320a of the insulation layer 320 in the direction Z, and a ratio of the distance D to a thickness 330T of the conductive layer 330 in the direction Z is greater than or equal to 0.02 and less than or equal to 0.1 (0.02≤D/300T≤0.1). In some embodiments, as shown in FIG. 1, the electronic device ED may further include a protection layer 400, wherein the protection layer 400 may surround the semiconductor structure 100 and the insulation layer 200 to keep moisture and air out and/or to reduce damage to the semiconductor structure 100.

According to an embodiment shown in FIG. 2, in a cross-sectional structure of the electronic device ED, one opening 210 of the insulation layer 200 may have a bottom width WB in the direction X, a maximum width of the connection pad 110 of the semiconductor structure 100 in the direction X is defined as a width W1 (or may be referred as the first width), and the bottom width WB is less than the width W1. In addition, the conductive layer 310 may contact at least 55% of an area of the connection pad 110, such that a ratio of an area of a portion of one connection pad 110 in contact with the conductive layer 310 to an entire area of the connection pad 110 may be greater than or equal to 0.55. In the cross-sectional structure of the electronic device ED, the opening 210 of the insulation layer 200 may have a top width WT in the direction X, and a ratio of the bottom width WB to the top width WT is greater than or equal to 0.5 and less than 1 (0.5≤WB/WT<1). In some embodiments, the top width WT of the opening 210 may be 21.2 micrometers (μm), and the bottom width WB of the opening 210 may be 13.9 μm, but not limited thereto. In another embodiment, the top width WT of the opening 210 may be 24.2 μm, and the bottom width WB may be 14.8 μm, but not limited thereto. In some embodiments, the width W1 of the connection pad 110 may be greater than or equal to the top width WT of the opening 210, but not limited thereto.

In some embodiments, as shown in FIG. 2, the insulation layer 200 may have a thickness T3 in the direction Z, a shortest distance S1 may be between two portions of the conductive layer 310 respectively disposed in the two adjacent openings 210 in the direction X, and a ratio of the thickness T3 to the distance S1 may be greater than or equal to 0.6 and less than or equal to 1.2 (0.6≤T3/S1≤1.2).

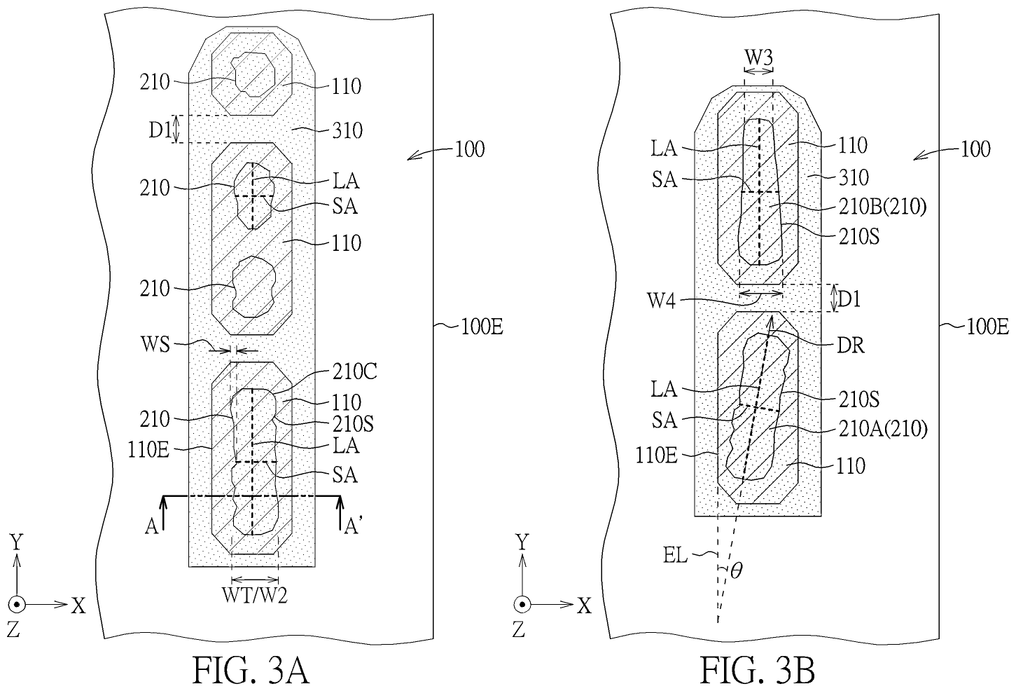

Refer to FIG. 3A and FIG. 1. FIG. 3A schematically illustrates a partial top view of a connection pad and an opening according to some embodiments of the present disclosure, and a cross-sectional structure corresponding to a line A-A′ in FIG. 3A may refer to a region R2 in FIG. 1. It is noted that the appearance of the connection pad 110 and the opening 210 of the electronic device ED of the present disclosure may be any kind or multiple kinds of the opening 210 shown in FIG. 3A and the opening 210A and opening 210B shown in the following FIG. 3B. According to an embodiment shown in FIG. 3A, in a top view of the electronic device ED along a direction opposite to the direction Z, the opening 210 of the insulation layer 200 has a major axis LA and a minor axis SA, wherein an extending direction of the major axis LA is perpendicular to an extending direction of the minor axis SA, and a ratio of a length of the minor axis SA to a length of the major axis LA may be greater than or equal to 0.15 and less than or equal to 0.7. Specifically, a greatest length of the opening 210 in a direction may be taken as the major axis LA, and then, the minor axis SA of the opening 210 may be obtained along a direction perpendicular to the direction of the major axis LA at a central point of the major axis LA. In some embodiments, the extending direction of the major axis LA may be parallel to the direction Y, and the extending direction of the minor axis SA may be parallel to the direction X, but not limited thereto. In some embodiments, in the top view of the electronic device ED, a shape of the opening 210 may be a stripe extending along the direction Y and one or more of its four vertices 210C (which may be referred to as corners) may include an arc-shape. In some other embodiments, the shape of the opening 210 may be oval, but not limited thereto. As shown in FIG. 3A, the openings 210 may correspond to the connection pads 110 in a one-to-one or a multiple-to-one way, a portion of the conductive layer 310 is disposed in each of the openings 210, and the conductive layer 310 is at least partially overlapped with the connection pads 110 in the direction Z. According to some embodiments, the distance D1 between the two adjacent connection pads 110 may be greater than or equal to 5 μm and/or less than or 20 μm, but not limited thereto.

As shown in FIG. 3A, in the top view of the electronic device ED along the direction opposite to the direction Z, a side edge of the opening 210 of the insulation layer 200 may have a wave-shaped outline 210S, and a width WS of the wave-shaped outline 210S in a direction perpendicular to the major axis LA ranges from 0.1 μm to 3 μm. Specifically, in the top view of the electronic device ED, the side edge of the opening 210 may have a plurality of protrusions comparatively closer to a side edge 110E of the connection pad 110 and a plurality of dents comparatively away from the side edge 110E, such that the wave-shaped outline 210S may be formed, wherein the side edge 110E of the connection pad 110 may (but not limited thereto) be parallel to the direction Y. A maximum distance between the protrusion and the dent of the wave-shaped outline 210S measured in the direction perpendicular to the major axis LA (a direction parallel to the minor axis SA, such as the direction X) may be the width WS, and the width WS may be greater than or equal to 0.1 μm and less than or equal to 3 μm. In some embodiments, in the top view of the electronic device ED, the opening 210 may have a width W2 (which may be referred as the second width) in the direction perpendicular to the major axis LA (e.g., the direction X), and a ratio of the width WS of the wave-shaped outline 210S to the width W2 may be greater than or equal to 0.2 and less than or equal to 0.6 (0.2≤WS/W2≤0.6), wherein the width W2 of the opening 210 shown in FIG. 3A is the top width WT of the opening 210 (shown in FIG. 2).

Refer to FIG. 3B. FIG. 3B schematically illustrates a partial top view of a connection pad and an opening according to some other embodiments of the present disclosure. According to an embodiment shown in FIG. 3B, one of the openings 210 included by the insulation layer 200 may be an opening 210A, wherein the opening 210A has the major axis LA and the minor axis SA, the extending direction of the major axis LA of the opening 210A may be parallel to a direction DR, and the extending direction of the minor axis SA may be perpendicular to the major axis LA. An extending line EL may be taken from the side edge 110E of the connection pad 110, and an included angle θ between the direction DR and the extending line EL of the side edge 110E of the connection pad 110 may be greater than or equal to 0 degrees and less than or equal to 20 degrees. In some other embodiments, one of the openings 210 included by the insulation layer 200 may be an opening 210B, and the opening 210B may be a stripe that is narrower on its top portion and wider on its bottom portion. Specifically, one end (e.g., a top end) of the opening 210B may have a width W3 in a direction perpendicular to its major axis LA, another end (e.g., a bottom end) of the opening 210B may have a width W4 in the direction perpendicular to its major axis LA, and the width W4 is greater than the width W3. For example, the width W3 may be a shortest width of the opening 210B in the direction X, and the width W4 may be a greatest width of the opening 210B in the direction X. A ratio of the width W3 to the width W4 may be greater than or equal to 0.8 and less than or equal to 1.2 to avoid causing parasitic capacitance or other electrical anomalies, but not limited thereto.

As shown in FIG. 3A and FIG. 3B, in some embodiments, an included angle between the two minor axes SA or the two major axes LA of the two adjacent openings 210 (e.g., the opening 210A and the opening 210B shown in FIG. 3B) may be greater than or equal to 0 degrees and less than or equal to 20 degrees to avoid causing manufacturing problems, such as cramped wirings, etc. In some embodiments, the extending direction of the major axis LA of at least one of the openings 210 may be parallel to a side edge 100E of the semiconductor structure 100, or an included angle between the extending direction of the major axis LA of at least one of the openings 210 and the side edge 100E of the semiconductor structure 100 may be greater than or equal to 0 degrees and less than or equal to 20 degrees.

According to all aforementioned structural designs of the connection pads 110 of the semiconductor structure 100 and the openings 210 overlapping the connection pads 110, the contact area between the conductive layer 310 disposed in the opening 210 and the connection pad 110 may be increased, such that the contact resistance between the conductive layer 310 and the connection pad 110 may be reduced, which enhances the conductivity quality.

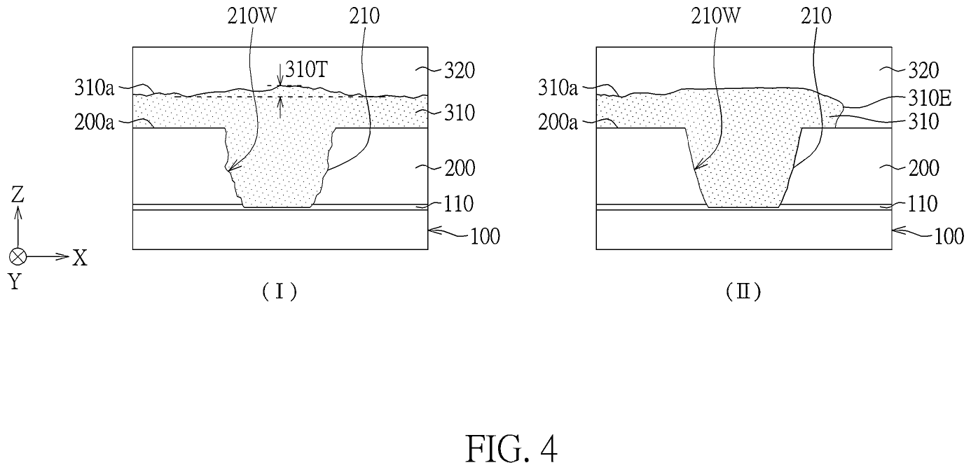

Refer to FIG. 4. FIG. 4 schematically illustrates a partial enlarged view of an electronic device according to some embodiments of the present disclosure, wherein the cross-sectional structure shown in FIG. 4 may refer to the region R2 in FIG. 1. According to an embodiment shown in an example (I) and an example (II) of FIG. 4, a side wall 210W of the opening 210 of the insulation layer 200 may have a rough surface, and a roughness of the side wall 210W of the opening 210 may be greater than a roughness of an upper surface 200a of the insulation layer 200 for enhancing a bonding strength between the conductive layer 310 and the insulation layer 200 in the opening 210, such that the risk of fracture is reduced, and reliability is enhanced. This makes the conductive layer 310 and the connection pad 110 of the semiconductor structure 100 have a good electrical connection. The definition of the term “rough” may correspond to an observed distance of 0.15 μm to 1 μm between peaks and valleys of surface undulations of the object in the direction Z when viewed through an electron microscope. In some embodiments, the measurement of the roughness may include using a scanning electron microscope (SEM) or a transmission electron microscope (TEM) to observe peaks and valleys of surface undulations of the object in a proper magnified ratio, and comparing the surface undulations by taking a unit length (e.g., 10 μm), wherein the term “proper magnified ratio” means at least one surface may be observed with at least 10 peaks in the visual field in this magnified ratio.

In some embodiments, as shown in the example (I) of FIG. 4, the upper surface 310a of the conductive layer 310 may be a rough surface to enhance the bonding strength between the conductive layer 310 and the insulation layer 320. For example, a gap 310T may be between a highest point and a lowest point of the upper surface 310a of the conductive layer 310 in the direction Z. In some other embodiments, as shown in example (II) of FIG. 4, the side wall 210W of the opening 210 and the upper surface 310a of the conductive layer 310 may undergo the surface treatment and may have less roughness when compared with the example (II), and an end portion 310E on one side of the conductive layer 310 may have an arc-shaped surface. The method of the aforementioned surface treatment may include roughening the surface of the conductive layer 310 or the insulation layer 320 to enhance its bonding capability.

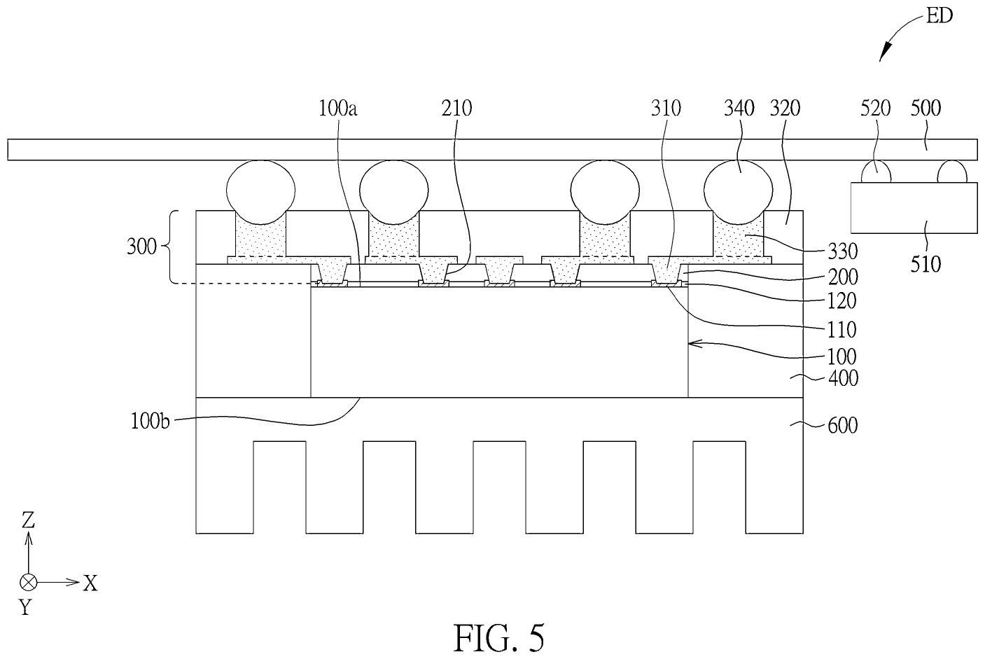

Refer to FIG. 5. FIG. 5 schematically illustrates cross-sectional view of an electronic device according to another embodiment of the present disclosure. According to an embodiment shown in FIG. 5, the electronic device ED may further include a circuit board 500, wherein the circuit board 500 may be disposed on the bonding elements 340, and the circuit board 500 may be electrically connected to the connection pads 110 of semiconductor structure 100 through the bonding elements 340, the conductive layer 330, and the conductive layer 310. The electronic device ED may further selectively include an electronic element 510, wherein the electronic element 510 may be electrically connected to the circuit board 500 through a bonding element 520, and the electronic element 510 may be disposed on one side of the semiconductor structure 100.

In some embodiments, as shown in FIG. 5, the electronic device ED may further selectively include a heat-dissipation element 600 disposed on one side of the semiconductor structure 100 opposite to the circuit structure 300. Specifically, the protection layer 400 may expose the rear surface 100b of the semiconductor structure 100, and the heat-dissipation element 600 may contact the rear surface 100b of the semiconductor structure 100. A thermal conductivity of the heat-dissipation element 600 may be greater than or equal to 50 Watt/meter·Kelvin (W/m·K) and less than or equal to 505 W/m·K. The heat-dissipation element 600 may, for example, include metal materials or other suitable heat conductive materials.

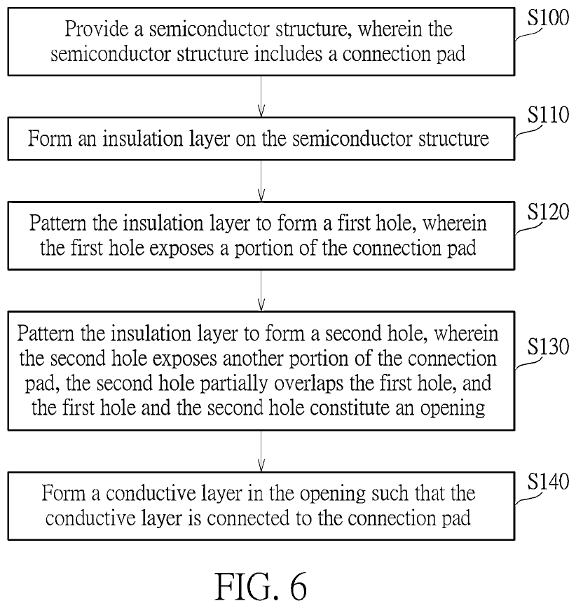

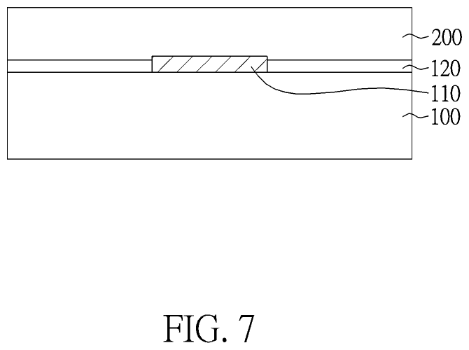

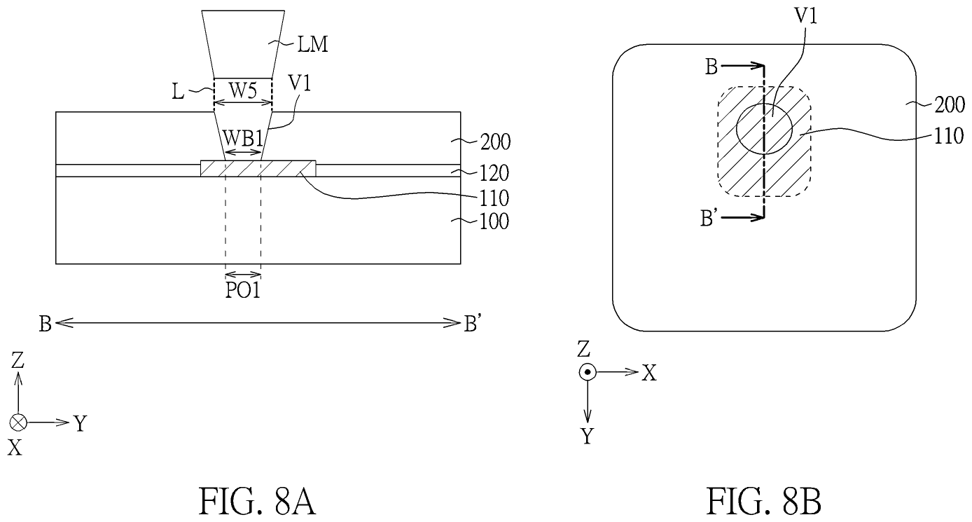

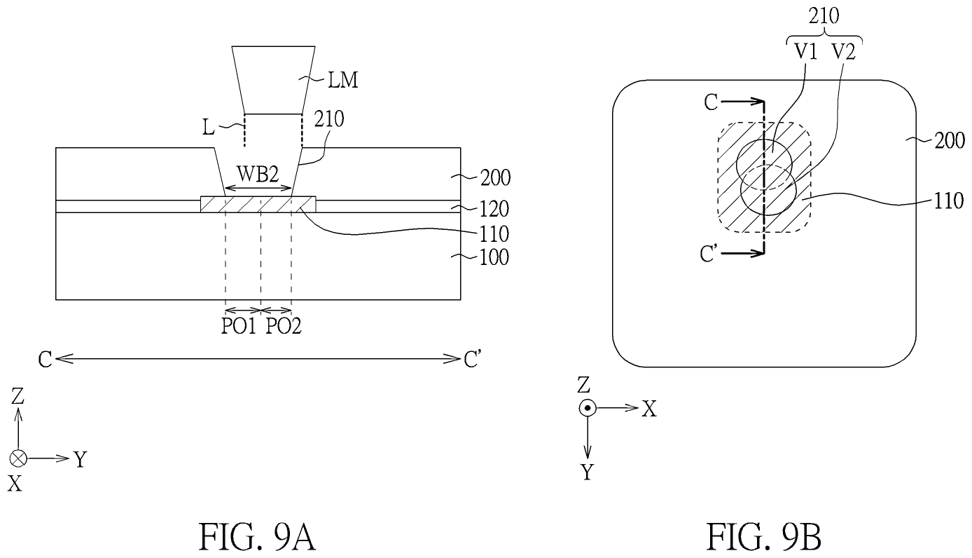

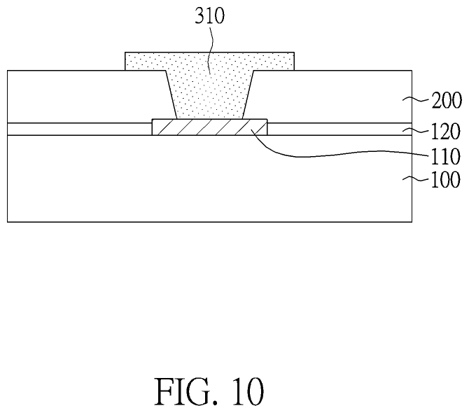

Refer to FIG. 6, FIG. 7, FIG. 8A, FIG. 8B, FIG. 9A, FIG. 9B, and FIG. 10. FIG. 6 schematically illustrates a flow chart of a manufacturing method of an electronic device according to an embodiment of the present disclosure. FIG. 7, FIG. 8A, FIG. 8B, FIG. 9A, FIG. 9B, and FIG. 10 schematically illustrate a partial process of a manufacturing method of an electronic device according to an embodiment of the present disclosure, wherein FIG. 8A schematically illustrates a partial cross-sectional structure corresponding to a line B-B′ in a top view shown in FIG. 8B, and FIG. 9A schematically illustrates a partial cross-sectional structure corresponding to a line C-C′ in a top view shown in FIG. 9B. As shown in FIG. 6, a manufacturing method of an electronic device of an embodiment of the present disclosure may include step S100 to step S140; the detailed descriptions are as follows. As shown in FIG. 7, step S100 may be performed to provide a semiconductor structure 100, wherein the semiconductor structure 100 includes a connection pad 110. The semiconductor structure 100 may further selectively include a passivation layer 120, wherein the passivation layer 120 may cover the side surface of the connection pad 110 and may expose the upper surface of the connection pad 110. Afterwards, step S110 may be performed to form an insulation layer 200 on the semiconductor structure 100.

As shown in FIG. 8A and FIG. 8B, step S120 may be performed to pattern the insulation layer 200 to form a first hole V1, wherein the first hole V1 exposes a portion PO1 of the connection pad 110. Afterwards, as shown in FIG. 9A and FIG. 9B, step S130 may be performed to pattern the insulation layer 200 to form a second hole V2, wherein the second hole V2 exposes another portion PO2 of the connection pad 110, the second hole V2 partially overlaps the first hole V1, and the first hole V1 and the second hole V2 constitute an opening 210 in the insulation layer 200. The second hole V2 may overlap at least 50% of an area of the first hole V1, e.g. 60%, 70%, 80%, or 90%, such that a ratio of a portion of the area of the first hole V1 overlapping the second hole V2 to the entire area of the first hole V1 may be greater than or equal to 0.5.

According to the embodiment shown in FIG. 8A, FIG. 8B, FIG. 9A, and FIG. 9B, patterning the insulation layer 200 to form the first hole V1 and the second hole V2 may be performed by a laser module LM, wherein laser L emitted by the laser module LM has a width W5 (which may be referred to as a third width) in the direction Y, the first hole V1 has a bottom width WB1 in the direction Y, and the width W5 of the laser L is greater than the bottom width WB1 of the first hole V1. In some embodiments, after forming the first hole V1, the laser module LM is then moved along the direction Y (which may be referred to as a first direction) to pattern the insulation layer 200 to form the second hole V2. As shown in FIG. 9B, a bottom width of the second hole V2 in the direction Y may be identical to the bottom width WB1 (marked in FIG. 8A) of the first hole V1. As shown in FIG. 9A, the opening 210 constituted by the first hole V1 and the second hole V2 has a bottom width WB2 in the direction Y, wherein the bottom width WB2 of the opening 210 is less than twice the bottom width WB1 of the first hole V1 (WB2<WB1*2) for the first hole V1 and the second hole V2 to have overlapping portions with each other in the two processes performed by the laser module LM.

After forming the opening 210, as shown in FIG. 10, step S140 may be performed to form a conductive layer 310 in the opening 210 such that the conductive layer 310 is connected to the connection pad 110. Specifically, the insulation layer 310 may be formed on the insulation layer 200, and a portion of the conductive layer 310 may be formed in the opening 210 of the insulation layer 200, such that the conductive layer 310 is overlapped with the connection pad 110 in the direction Z, and the conductive layer 310 may be electrically connected to and in contact with the connection pad 110 of the semiconductor structure 100 through the opening 210. The detailed structure of the opening 210 formed by the aforementioned manufacturing methods according to some embodiments may be known by referring to the embodiment shown in FIG. 2, FIG. 3A, and FIG. 3B, and it will not be redundantly detailed herein.

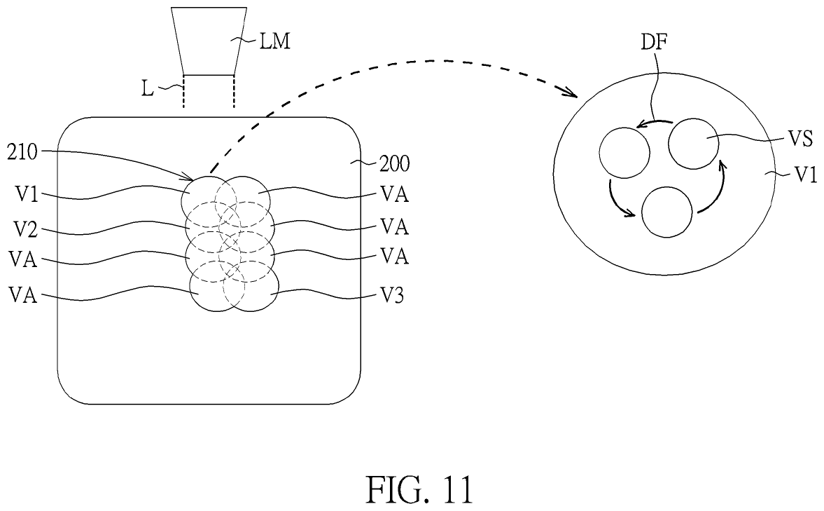

Refer to FIG. 11. FIG. 11 schematically illustrates a partial process of a manufacturing method of an electronic device according to an embodiment of the present disclosure. According to an embodiment shown in FIG. 11, according to the practical requirements of the bottom width of the opening 210 in the direction Y, after forming the second hole V2, the laser module LM may further be moved along the direction Y and may pattern the insulation layer 200 to form a plurality of holes VA overlapped with each other, such that still another portion of the connection pad 110 is exposed. The hole VA, which is formed first, may be overlapped with the hole VA which is formed subsequently. That is, the hole VA formed immediately after a first hole VA may be partially overlapped with the first hole VA formed immediately before: for example, the hole VA formed immediately after the first hole VA may be overlapped with at least 50% of an area of the first hole VA formed immediately before. The method of forming the holes VA may be known by referring to the method of forming the first hole V1 and the second hole V2.

When the plurality of holes overlapped with each other (e.g., the first hole V1, the second hole V2, and the plurality of holes VA shown in FIG. 11) is formed by the laser module LM through multiple processes, the side edge of the opening 210, which is constituted by the plurality of holes, may form the wave-shaped outline 210S (as shown in FIG. 3A and FIG. 3B) and may further form the recess on the surface of the first portion P1 of the connection pad 110 (as shown in FIG. 2).

In some embodiments, as shown in FIG. 11, after sequentially forming the first hole V1, the second hole V2, and the other following holes VA, the laser module LM may be moved along the direction X (which may be referred to as the second direction). Then, a third hole V3 may be formed by the laser module LM patterning the insulation layer 200, the third hole V3 may expose a further portion of the connection pad 110, and the third hole V3 may be partially overlapped with one of or multiple holes VA. Afterwards, the laser module LM may be moved along a direction opposite to the direction Y, and the plurality of holes VA may be formed by the laser module LM patterning the insulation layer 200 to finally constitute the opening 210 with the major axis and the minor axis. In some other embodiments, according to practical requirements of the bottom width of the opening 210 in the direction X, after forming the third hole V3, the laser module LM may first continue to be moved along the direction X and may pattern the insulation layer 200 to form the plurality of holes VA overlapped with each other. As the required bottom width of the opening 210 in the direction X is met, the laser module LM may then be moved along the direction opposite to the direction Y to pattern the insulation layer 200.

In some embodiments, as shown in the enlarged process on the right side of FIG. 11, forming the first hole V1 may further include: moving the laser module LM clockwise or counterclockwise to form a plurality of sub-holes VS, wherein the plurality of sub-holes VS may constitute the first hole V1. For example, the laser module LM may be moved clockwise along a moving direction DF (indicated with multiple arrows in FIG. 11) to form the plurality of sub-holes VS, wherein the plurality of sub-holes VS may partially overlap each other to finally constitute the first hole V1 having a greater size. Similarly, in the formation of the second hole V2, the laser module LM may be moved clockwise or counterclockwise to form the plurality of sub-holes VS, wherein the plurality of sub-holes VS may partially overlap each other to finally constitute the second hole V2 having a greater size. The process of forming the holes VA or forming the third hole V3 may also be inferred from the above-mentioned contents.

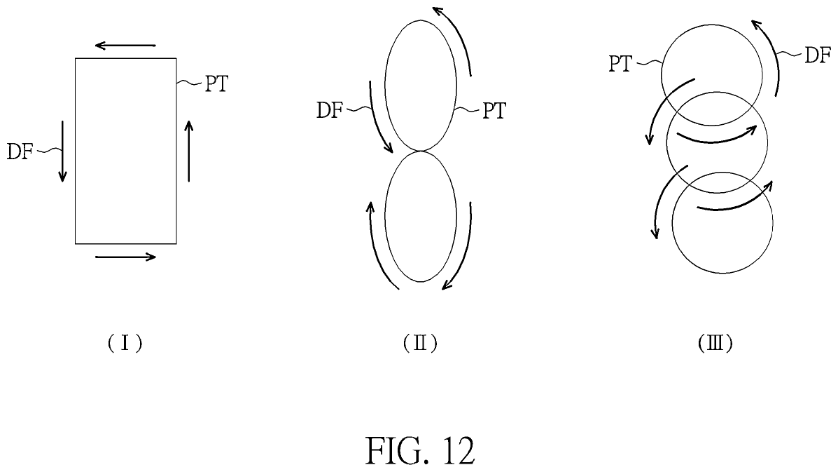

Refer to FIG. 12. FIG. 12 schematically illustrates a moving path of a laser module according to some embodiments of the present disclosure. According to an embodiment shown in an example (I), an example (II), and an example (III) of FIG. 12, the laser module LM (shown in FIG. 8A) may be moved along a path PT in the moving direction DF (indicated with multiple arrows in FIG. 12) to form the plurality of holes, such that the openings 210 shown in FIG. 3A or FIG. 3B are constituted. The path PT may be an encircled shape shown in example (I), a figure eight shape shown in example (II), or a spring shape shown in example (III), but not limited thereto.

The electronic device and the manufacturing method thereof provided by the present disclosure include using the laser module LM being moved along a designed path to form holes repetitively in a certain region of the insulation layer 200, such that the formed holes may at least partially overlap each other. Therefore, the openings 210 (that is the contact holes) formed last may have a greater opening area, such that the conductive layer 310 formed later in the openings 210 and the connection pad 110 below the openings 210 may have a better conductivity, and the contact resistance between the conductive layer 310 and the connection pad 110 may be reduced. Compared with the traditional method of forming the opening through an etching process, the method of forming the openings 210 with the laser module LM may control the position, size, and/or outlines (including outlines in the top view and side wall outlines in the cross-sectional view) of the opening more effectively, such that a better yield of manufacturing the openings may be provided.

In summary, according to the electronic device and the manufacturing method thereof provided by the embodiments of the present disclosure, via the structural design of the connection pad of the semiconductor structure and the opening overlapped with the connection pad, the contact area between the conductive layer disposed in the opening and the connection pad may be increased to reduce contact resistance between the conductive layer disposed in the opening and the connection pad, such that the conductivity quality is enhanced.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a semiconductor structure, comprising a connection pad, wherein the connection pad comprises a first portion and a second portion, and the first portion is connected to the second portion;
an insulation layer disposed on the semiconductor structure, wherein the insulation layer comprises an opening, and the opening exposes the first portion of the connection pad; and
a circuit structure disposed on the insulation layer, wherein the circuit structure comprises a conductive layer, and the conductive layer is disposed in the opening and overlapped with the first portion of the connection pad,
wherein the first portion of the connection pad has a first thickness, the second portion of the connection pad has a second thickness, and a ratio of the second thickness to the first thickness is greater than or equal to 1 and less than or equal to 1.3.

2. The electronic device according to claim 1, wherein in a cross-sectional structure of the electronic device, the opening has a bottom width, the connection pad has a first width, and the bottom width is less than the first width.

3. The electronic device according to claim 2, wherein the conductive layer contacts at least 55% of an area of the connection pad.

4. The electronic device according to claim 2, wherein in the cross-sectional structure, the opening has a top width, and a ratio of the bottom width to the top width is greater than or equal to 0.5 and less than 1.

5. The electronic device according to claim 1, wherein in a top view of the electronic device, the opening has a major axis and a minor axis, and an extending direction of the major axis is perpendicular to an extending direction of the minor axis.

6. The electronic device according to claim 5, wherein a ratio of a length of the minor axis to a length of the major axis is greater than or equal to 0.15 and less than or equal to 0.7.

7. The electronic device according to claim 5, wherein an included angle between the extending direction of the major axis and an extending line of a side edge of the connection pad is greater than or equal to 0 degrees and less than or equal to 20 degrees.

8. The electronic device according to claim 5, wherein in the top view of the electronic device, a corner of the opening comprises an arc-shape.

9. The electronic device according to claim 1, wherein in a top view of the electronic device, a side edge of the opening has a wave-shaped outline, and a width of the wave-shaped outline in a direction ranges from 0.1 micrometers to 3 micrometers.

10. The electronic device according to claim 9, wherein in the top view of the electronic device, the opening has a second width in the direction, and a ratio of the width of the wave-shaped outline to the second width is greater than or equal to 0.2 and less than or equal to 0.6.

11. A manufacturing method of an electronic device, comprising:
providing a semiconductor structure, wherein the semiconductor comprises a connection pad;
forming an insulation layer on the semiconductor structure;
patterning the insulation layer to form a first hole, wherein the first hole exposes a portion of the connection pad;
patterning the insulation layer to form a second hole, wherein the second hole exposes another portion of the connection pad, the second hole partially overlaps the first hole, and the first hole and the second hole constitute an opening; and
forming a conductive layer in the opening such that the conductive layer is connected to the connection pad.

12. The manufacturing method of the electronic device according to claim 11, wherein the second hole overlaps at least 50% of an area of the first hole.

13. The manufacturing method of the electronic device according to claim 11, wherein the opening has a major axis and a minor axis, and a ratio of a length of the minor axis to a length of the major axis is greater than or equal to 0.15 and less than or equal to 0.7.

14. The manufacturing method of the electronic device according to claim 11, wherein a side edge of the opening has a wave-shaped outline, and a width of the wave-shaped outline in a direction ranges from 0.1 micrometers to 3 micrometers.

15. The manufacturing method of the electronic device according to claim 11, wherein patterning the insulation layer to form the first hole and the second hole is performed by a laser module.

16. The manufacturing method of the electronic device according to claim 15, wherein a laser emitted by the laser module has a third width in a direction, and the third width is greater than a bottom width of the first hole in the direction.

17. The manufacturing method of the electronic device according to claim 16, wherein a bottom width of the opening in the direction is less than twice the bottom width of the first hole.

18. The manufacturing method of the electronic device according to claim 15, wherein after forming the first hole, the laser module is moved along a first direction to pattern the insulation layer to form the second hole.

19. The manufacturing method of the electronic device according to claim 18, further comprising:
after forming the second hole, moving the laser module along a second direction, wherein the second direction is perpendicular to the first direction; and
patterning the insulation layer by the laser module to form a third hole, wherein the third hole exposes a further portion of the connection pad.

20. The manufacturing method of the electronic device according to claim 15, wherein forming the first hole comprises:
moving the laser module clockwise or counterclockwise to form a plurality of sub-holes, wherein the plurality of sub-holes constitute the first hole.
